(19) United States
(12) Patent Application Publication
(10) Pub. No.: US 2026/0098741 A1
(43) Pub. Date: Apr. 9, 2026

(54) VEHICLE HOME SETTING DEVICED

(71) Applicant: NISSAN NORTH AMERICA, INC., Franklin, TN (US)

(72) Inventors: Aaron Isaac KANDEL, San Francisco, CA (US); Yoshinori SUZUE, Mountain View, CA (US)

(21) Appl. No.: 18/907,458

(22) Filed: Oct. 4, 2024

(51) Int. Cl. G01C 21/00; G01R 31/382

(52) U.S. Cl. CPC G01C 21/3811; G01R 31/382

(57) ABSTRACT

A vehicle home setting device includes a vehicle tracking unit, a non-transitory computer readable medium and an electronic controller. The vehicle tracking unit electronically collects vehicle visit locations of the vehicle. The non-transitory computer readable medium electronically stores the vehicle visit locations during vehicle travel, and stores vehicle roundtrip travel information having corresponding vehicle start and stop locations that are the same. The electronic controller is programmed to categorize the end locations as one or more home locations of the vehicle based on a calculated number of the intermediary stop locations for vehicle roundtrip travel. The intermediary stop locations are locations that are visited by the vehicle during vehicle roundtrip travel that does not include the start and stop location in which the vehicle is turned off.

### BACKGROUND

### Technical Field

The present disclosure generally relates to a vehicle home setting device. More specifically, the present disclosure relates to a vehicle home setting device for categorizing and determining a home location for the vehicle from among vehicle visit locations.

### Background Information

Conventional home determination is based on frequency of visits or time of the of the visit. However, these factors can be misleading for certain users, such as those that are nighttime workers, frequent travelers, or someone with shared or multiple homes. The determination of home location for the vehicle can impact vehicle charging schedules if the vehicle is an EV, engine control, and more.

### SUMMARY

In view of the state of the known technology, one aspect of the present disclosure is to provide a vehicle home setting device comprises a vehicle tracking unit, a non-transitory computer readable medium and an electronic controller. The vehicle tracking unit electronically collects vehicle visit locations of the vehicle. The non-transitory computer readable medium electronically stores the vehicle visit locations during vehicle travel, and stores vehicle roundtrip travel information having corresponding vehicle start and stop locations that are the same. The electronic controller is programmed to categorize the end locations as one or more home locations of the vehicle based on a calculated number of the intermediary stop locations for vehicle roundtrip travel. The intermediary stop locations are locations that are visited by the vehicle during vehicle roundtrip travel that does not include the start and stop location in which the vehicle is turned off.

In view of the state of the known technology, another aspect of the present disclosure is to provide a method for determining a vehicle home location from among a plurality of vehicle visit locations. The method comprises electronically collecting, by a vehicle tracking unit, vehicle visit locations of the vehicle during vehicle travel. The vehicle visit locations include vehicle trip start locations, vehicle trip end locations and vehicle trip intermediary stop locations visited between corresponding start and end locations. The method further comprises electronically storing, by a non-transitory computer readable medium, the vehicle visit locations during vehicle travel. The non-transitory computer readable medium stores vehicle roundtrip travel information having corresponding vehicle start and stop locations that are the same. The method further comprises categorizing, by an electronic controller, the end locations as one or more home locations of the vehicle in the non-transitory computer readable medium based on a calculated number of the intermediary stop locations for vehicle roundtrip travel. The intermediary stop locations are locations that are visited by the vehicle during vehicle roundtrip travel that does not include the start and stop location in which the vehicle is turned off.

### BRIEF DESCRIPTION OF THE DRAWINGS

Referring now to the attached drawings which form a part of this original disclosure:

FIG. 1 is a schematic diagram of a vehicle control system having a vehicle home determination setting device and a vehicle control device in accordance with an illustrated embodiment;

FIG. 2 is a schematic diagram of a vehicle equipped with the vehicle home determination setting device;

FIG. 3 is a schematic view of sample vehicle history information that is stored in the storage of the vehicle home setting device;

FIG. 4 is additional schematic view of sample vehicle history information that is stored in the storage of the vehicle home setting device in which a home location has been calculated;

FIG. 5 is a schematic diagram of a pure roundtrip scenario having zero intermediary stops between a vehicle start and end location;

FIG. 6 is a schematic diagram of a roundtrip scenario having one intermediary stop between a vehicle start and end location;

FIG. 7 is a schematic diagram of roundtrip scenarios having two intermediary stops between a vehicle start and end location;

FIG. 8 is a schematic diagram of roundtrip scenarios having three intermediary stops between a vehicle start and end location;

FIG. 9 is a flowchart illustrating the steps executed by the electronic controller of the vehicle home setting device; and

FIG. 10 is an additional schematic view of sample of vehicle history information that is stored in the storage of the vehicle home setting device having corresponding state-of-charge data.

### DETAILED DESCRIPTION OF EMBODIMENTS

Selected embodiments will now be explained with reference to the drawings. It will be apparent to those skilled in the art from this disclosure that the following descriptions of the embodiments are provided for illustration only and not for the purpose of limiting the invention as defined by the appended claims and their equivalents.

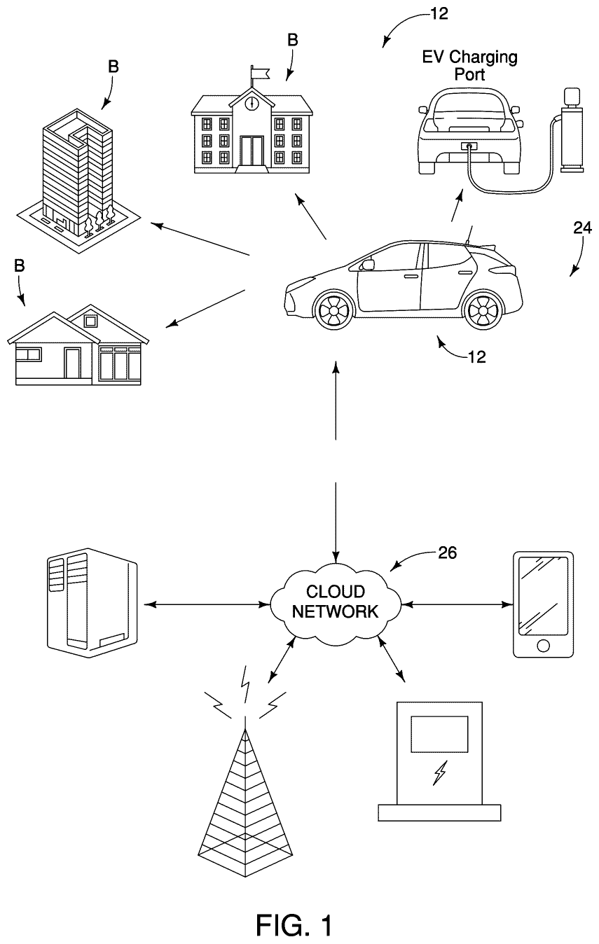

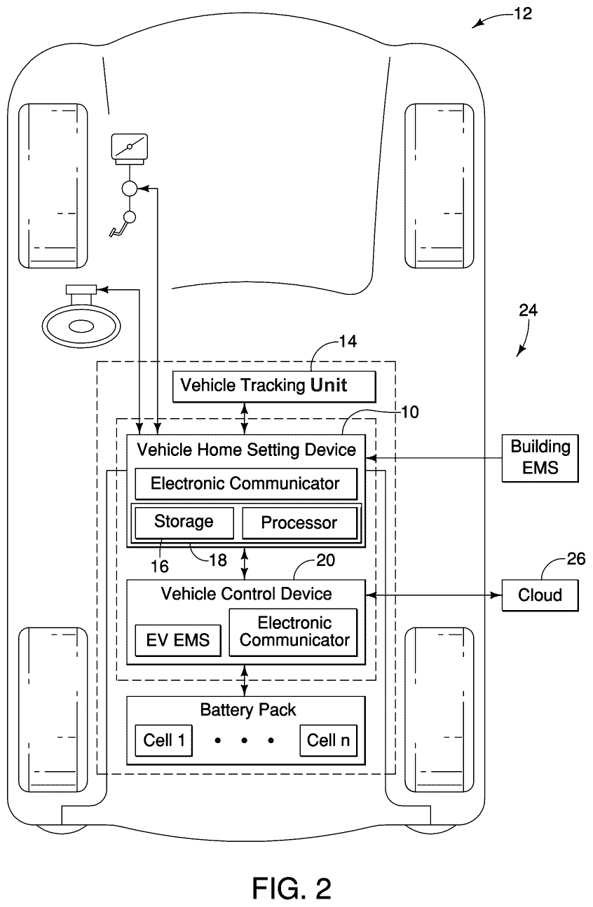

Referring initially to FIGS. 1 and 2, a vehicle home setting device 10 to be implemented for a vehicle 12 is illustrated in accordance with an embodiment. The vehicle home setting device 10 comprises a vehicle tracking unit 14 for the vehicle 12, a non-transitory computer readable medium (hereinafter storage 16) and an electronic controller 18. Also shown in FIG. 1, a vehicle control device 20 is illustrated in accordance with the embodiment. The vehicle control device 20 can be implemented with the vehicle home setting device 10 and the vehicle 12 and can include components of the vehicle home setting device 10.

The vehicle home setting device 10 provides an improved device and method for determining a vehicle home location. In particular, the vehicle home setting device 10 is provided to categorize vehicle visit locations as potential home locations and can dynamically update the designated home location based on vehicle travel history, as will be described below. The vehicle control device 20 provides a technically improved device in the technical field of generating charging schedules for the vehicle 12 which can be an electric vehicle. The vehicle control device 20 provides a technological improvement for generating the charging schedules which can be based on vehicle travel history and the home determination of the vehicle home setting device 10, as will be described below. In the illustrated embodiment, the term “charging schedule(s)” will refer to a charge level with respect to time graph or chart for determining a rate or degree of vehicle charging with respect to time.

In the illustrated embodiment, the term “home location” or “home locations” include one or more locations that are visited by the vehicle 12 that is designated by the electronic controller 18 to be the location in which the vehicle 12 spends more time relative to other locations. The electronic controller 18 designates or categorizes these “home locations” in the storage 16, which can be updated over time depending on vehicle behavior. That is, the home location can be updated over time as the vehicle 12 travels. The home location categorization can be used to better determine vehicle charging demand maps or schedules for the vehicle if the vehicle is an electric vehicle, as will be further described below.

Together, the vehicle home setting device 10 and the vehicle control device 20 can be considered components of a vehicle control system C illustrated in FIGS. 1 and 2. The electronic controller 18 of the vehicle control system C described herein can include one or more electronic controller(s) 18 that are provided to the vehicle home setting device 10 and the vehicle control device 20. The electronic controller(s) 18 can be provided on-board the vehicle 12. Alternatively, the electronic controller(s) 18 can be provided to an external network, such as a cloud network 26 that is in electronic communication with the vehicle 12, as described herein. Therefore, the calculations, determinations and method executed by the electronic controller(s) 18 described herein can occur either on-board the vehicle 12 or on the external network or cloud network 26.

As seen in FIG. 2, the vehicle 12 is preferably equipped with an electric communicator to enable wireless communications between the vehicle tracking unit 14, the vehicle 12 and the cloud 26. Therefore, the electronic controller 18 of the illustrated embodiment preferably includes an electronic communicator such as a wireless communication device. The term “electronic communicator” as used herein includes a receiver, a transmitter, a transceiver, a transmitter-receiver, and contemplates any device or devices, separate or combined, capable of transmitting and/or receiving wireless communication signals, including shift signals or control, command or other signals related to some function of the component being controlled. The wireless communication signals can be radio frequency (RF) signals, ultra-wide band communication signals, or Bluetooth communications or any other type of signal suitable for wireless communications as understood in the bicycle field.

Additionally, the storage 16 stores the vehicle visit locations and the home location(s) that are categorized by the electronic controller 18. As with the electronic controller 18, the storage 16 can be provided on-board the vehicle 12 or alternatively, to the external network, such as the cloud 26. Therefore, the storage 16 and the electronic controller 18 are provided on one or the other of the on-board network of the vehicle 12 and the external network that is external to the vehicle and the building structure B.

As shown FIG. 1, the vehicle control device 20 having an energy management system (EV EMS) is to be implemented with a vehicle charging structure, such as a building structure B having one or more charging ports for charging electric vehicles EV when the electric vehicles EV are plugged into the charging ports. The charging ports are connected to an electric source that powers the building structure B. The electric source can be a traditional electric source, such as an electric grid. Alternatively, the electric source can be forms of renewable energy such as solar panels that are installed to the building structure B.

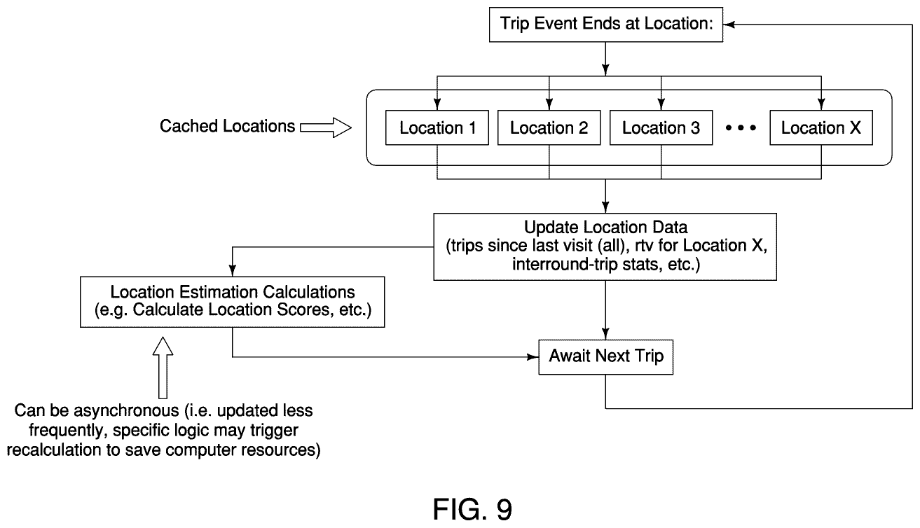

Referring to FIGS. 1 to 10, the vehicle home setting device 10 will be further described. As stated, the vehicle home setting device 10 includes the vehicle tracking unit 14 which is provided on-board the vehicle 12. The vehicle tracking unit 14 electronically tracks and records vehicle visit locations of the vehicle during vehicle travel. In the illustrated embodiment, the vehicle visit locations include vehicle trip start locations, vehicle trip end locations and vehicle trip intermediary stop locations visited between corresponding start and end locations. In the illustrated embodiment, the intermediary stop locations are visited during vehicle roundtrips.

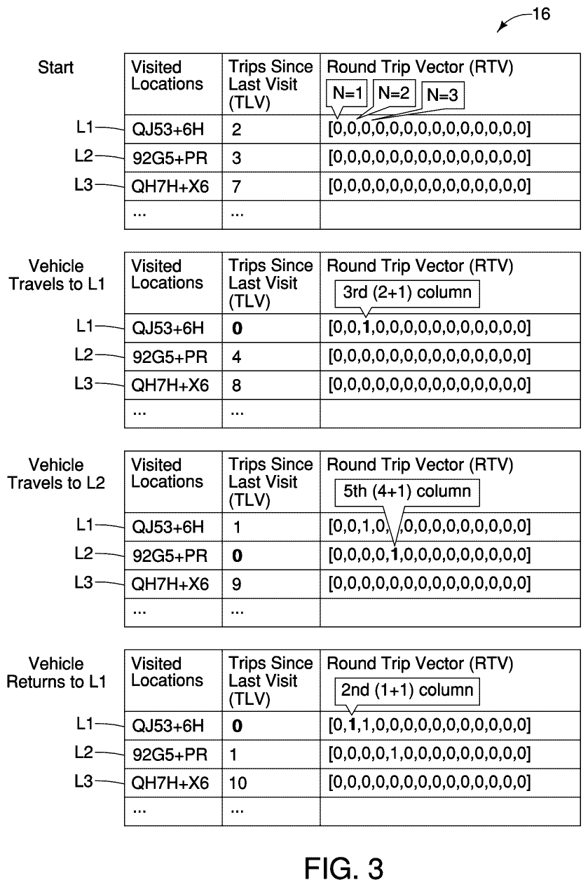

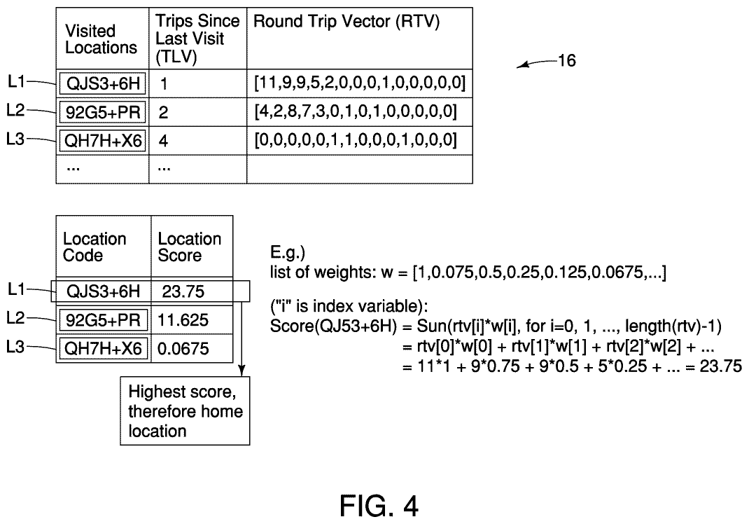

Therefore, the vehicle home setting device 10 determines whether an end location of a vehicle trip should be designated a home location based on a total number or total count of intermediary stop locations that are visited prior to arriving at the end location. In particular, the intermediary stop locations are based on vehicle roundtrip travel. Therefore, the start and end locations of vehicle roundtrips are the same. That is, in the illustrated embodiment, the term “intermediary stop location(s)” refer to location(s) that are visited by the vehicle during vehicle roundtrip travel that does not include the start and stop location in which the vehicle is turned OFF. For example, as shown in FIGS. 3 and 4, the vehicle start and end locations are illustrated as “visited locations.” Therefore, the storage 16 stores vehicle roundtrip travel information having corresponding vehicle start and stop locations that are the same.

Preferably, the vehicle visit locations are established based on a determination that the vehicle 12 has turned OFF (i.e., the vehicle engine is OFF). That is, a newly visited location is established as a vehicle visit location by the vehicle tracking unit 14 upon the engine shutting OFF. The visited location is then stored as part of the vehicle visit locations are stored in the storage 16.

In the illustrated embodiment, the electronic controller 18 is programmed to determine whether a vehicle visit location should be set as the home location for the vehicle 12 based on a history of intermediary stop locations that are visited prior to returning to the vehicle visit location during vehicle travel. Broadly speaking, the electronic controller 18 is programmed to set the vehicle visit location as the home location due to having a history of fewer recorded intermediary stop locations prior to returning to the visit location as the end location during vehicle travel, as will be further described below.

Referring to FIG. 2, the vehicle tracking unit 14 can include a global positioning device (GPS) and a telemetry control unit. Therefore, the telemetry control unit can be an embedded computer system that wirelessly connects the vehicle to cloud 26 services or other the vehicle network via vehicle-to-everything (V2X standards) over a cellular network. The telemetry control unit collects telemetry data regarding the vehicle, such as position, speed, engine data, connectivity quality etc. by interfacing with various sub-systems and control busses in the vehicle 12. The telemetry control unit can also provide in-vehicle connectivity via Wi-Fi and Bluetooth. The telemetry control unit can include an electronic processing unit, a microcontroller, a microprocessor or field programmable gate array (FPGA), which processes information and serves to interface with the GPS unit. The vehicle tracking unit 14 can include a mobile communication unit and memory for saving GPS values in case of mobile-free zones or to intelligently store information about the vehicle's sensor data.

As stated, the storage 16 can be provided on a cloud 26 or a cloud network 26 that is external of the vehicle 12 and in electronic communication with the vehicle 12. In this case, the vehicle tracking unit 14 can communicate with the storage 16 via an access point. The access point can be a base station, a base transceiver station (BTS), a Node-B, an enhanced Node-B (eNode-B), a Home Node-B (HNode-B), a wireless router, a wired router, a hub, a relay, a switch, or any similar wired or wireless device. The vehicle 12 can communicate with the vehicle network via the vehicle tracking unit 14. In other words, the vehicle tracking unit 14 can be in communication via any wireless communication network such as high bandwidth GPRS/1×RTT channel, a wide area network (WAN) or local area network (LAN), or any cloud 26-based communication, for example. Therefore, using the vehicle tracking unit 14, the vehicle 12 can participate in a computing network or a cloud 26-based platform.

The electric communicator can also be a wireless communicator that includes a receiver, a transmitter, a transceiver, a transmitter-receiver, and contemplates any device or devices, separate or combined, capable of transmitting and/or receiving wireless communication signals, including shift signals or control, command or other signals related to some function of the component being controlled. The wireless communication signals can be radio frequency (RF) signals, ultra-wide band communication signals, or Bluetooth communications or any other type of signal suitable for wireless communications as understood in the vehicle field. Here, the electric communicator can be a one-way wireless communication unit such as a transmitter.

The electronic controller 18 is a computer that includes one or more processors to execute the functions of the vehicle home setting device 10. As used herein this disclosure, the terminology “processor” indicates one or more processors, such as one or more special purpose processors, one or more digital signal processors, one or more microprocessors, one or more controllers, one or more microcontrollers, one or more application processors, one or more Application Specific Integrated Circuits, one or more Application Specific Standard Products; one or more Field Programmable Gate Arrays, any other type or combination of integrated circuits, one or more state machines, or any combination thereof.

The processor can execute instructions transmitted by one or more transmission media, including coaxial cables, copper wire and fiber optics, including the wires that comprise a system bus coupled to a processor of a computer. As used herein, the terminology “instructions” may include directions or expressions for performing any method, or any portion or portions thereof, disclosed herein, and may be realized in hardware, software, or any combination thereof.

For example, instructions may be implemented as information, such as a computer program, stored in memory that may be executed by the processor to perform any of the respective methods, algorithms, aspects, or combinations thereof, as described herein. In some embodiments, instructions, or a portion thereof, may be implemented as a special purpose processor, or circuitry, that may include specialized hardware for carrying out any of the methods, algorithms, aspects, or combinations thereof, as described herein. In some implementations, portions of the instructions may be distributed across multiple processors on a single device, on multiple devices, which may communicate directly or across a network such as a local area network, a wide area network, the Internet, or a combination thereof.

Computer-executable instructions can be compiled or interpreted from computer programs created using a variety of programming languages and/or technologies, including, without limitation, and either alone or in combination, Java™, C, C++, Visual Basic, Java Script, Perl, etc. In general, the processor receives instructions from the storage 16 and executes these instructions, thereby performing one or more processes, including one or more of the processes described herein. Such instructions and other data may be stored and transmitted using a variety of computer-readable media.

Referring to FIG. 3, samples of vehicle travel history stored in the storage 16 are illustrated. As shown, the vehicle travel history is updated over time by the electronic controller 18 as the vehicle travels. For example, the vehicle travel history that is stored or recorded can include vehicle visit locations, “trips since last visit” TLV for each corresponding vehicle visit location, and indices N of “round-trip vector” values RTV for each corresponding vehicle visit location, as will be described below. As seen in FIG. 3, the storage 16 stores a plurality of roundtrip vector values RTV for each vehicle visit location. The roundtrip vector values RTV are based on a number of intermediary stop locations visited prior returning to each vehicle visit location as will be described below.

The value for the indices N of “round-trip vector” values RTV records the number of intermediary trips taken before returning to the corresponding visit location. In particular, the RTV values begin at zero (0) representing zero (0) intermediary trips, and increase by one (1) for each increasing index N.

As seen in FIG. 3, the storage 16 stores indices N of roundtrip vector values RTV in which each index of the indices N corresponds to a recorded number of intermediary stop locations visited prior to returning to each vehicle visit location such that a lower index corresponds to a lower recorded number of intermediary stop locations. That is, for the first index N=1 of the Location QJ53+6H, the RTV value is zero (0), which depicts zero (0) intermediary stops between starting and returning at the Location QJ53+6H. For the second index N=2 of the Location QJ53+6H, the RTV value is one (1), which depicts one (1) intermediary stop between starting and returning at the Location QJ53+6H, and so on.

The storage 16 electronically stores the vehicle visit locations during vehicle travel as it receives vehicle travel information from the vehicle tracking unit 14. The vehicle visit locations can be identified by a location code or a GPS latitude and longitudinal code. In FIG. 3, the sample visit locations that have been visited by the vehicle include locations QJ53+6H (alternatively Location 1 or L1), 92G5+PR (alternatively Location 2 or L2), QH7H+X6 (alternatively Location 3 or L3).

The storage 16 also records a number of “trips since last visit” TLV for each of the vehicle locations L1 to L3. Every time the vehicle 12 returns to any of the locations L1 to L3, the electronic controller 18 updates the TLV for the corresponding location L1 to L3 to zero (0). For example, when the vehicle 12 travels to L1 such that the vehicle 12 is turned OFF at L1 and L1 is deemed the end location for that vehicle trip, the electronic controller 18 updates the TLV for L1 to zero (0) trips. The electronic controller 18 also concurrently updates the TLV for L2 and L3 to increase by one (1) trip. That is, the TLV value for L2 is increased from three (3) to four (4) trips and the TLV value for L3 is increased from seven (7) to eight (8) trips.

Additionally, the electronic controller 18 updates the index N for RTV for L1. The updated index N is based on the TLV value for L1 prior to the update. That is, the recorded TLV for L1 was two (2) trips prior to the update to zero (0) trips since last visit, then the index N that is updated is the previous TLV value plus one (1) or (2+1). Therefore, the index N that is depicted is to be updated is the third index (N=3) of RTV for L1, which is updated from zero (0) to (1) trip to record an instance of three (3) intermediary trips taken since returning to the location L1.

In this example, the vehicle then travels from L1 to L2. When this occurs, the TLV value for L2 is updated from four (4) trips to zero (0) trips since last visit. Concurrently, the electronic controller 18 updates the TLV values for L1 and L3 to increase by one (1), such that the TLV value for L1 is increased to one (1) from zero, and the TLV value for L3 is increased to nine (9) from eight (8). The electronic controller 18 concurrently updates the index N for the RTV based on the prior TLV value for L2, which is four (4) trips. Therefore, the electronic controller 18 updates the fourth index N plus one (1) index for L2. That is, the electronic controller 18 updates the fifth index (N=5) for L2 from zero (0) to increase by one (1) trip to record an instance of four (4) intermediary trips taken since returning to L2. The electronic controller 18 then repeats this process as the vehicle 12 continues to travel and visit additional locations.

As the indices N of RTV are updated during vehicle travel, the storage 16 records ongoing values of intermediary stops visited for each location L1 to L3 prior to returning to that location. Referring to FIG. 4, the values stored in the indices N of RTV are used to calculate a location score for each stored location in order to determine and update the home location of the vehicle, as will be further described below. Therefore, the electronic controller 18 updates the vehicle travel history over time, as illustrated in FIGS. 3 and 4. Additionally, the home location is ultimately determined based on the number of intermediary visited locations, represented by stored indices N of RTVs for each location stored in the storage 16.

The home determination by the vehicle home setting device 10 of the illustrated embodiment is programmed to be biased towards categorizing locations with higher values for a lower indices ((e.g., the first N (N=1) or the second index N (N=2)). In other words, locations having more recorded trips for lower indices N is categorized with a higher location score that deems the locations to be more likely to be the vehicle home location. That is, the vehicle home setting device 10 is programmed with logic that assumes that vehicle locations that are returned to having the fewest number of intermediary stops visited prior to returning is more likely the home location.

Conventional home determination is based on frequency of visits or time of the of the visit. However, these factors can be misleading for certain users, such as those that are nighttime workers, frequent travelers, or someone with shared or multiple homes. Despite these variables, a true home location will be preceded by higher density of short trips, represented by higher values for lower indices N for the RTV. To simplify, a location having a first index N (N=1) with an RTV value of eleven (11) will be biased to be considered the home location over a location having a first index N (N=1) with an RTV value that is less than eleven (11).

Referring to FIG. 4, a fuller sample of vehicle visit locations is illustrated for locations L1 to L3 having more progressed vehicle visit locations stored. As shown for L1, the first index N=1 has an RTV value of eleven (11) which means that there were eleven (11) recorded roundtrips having zero (0) intermediary stop for L1. For the second index N=2 of L1, the RTV value is nine (9) meaning there were nine (9) recorded roundtrips having one (1) intermediary stop for L1.

In the illustrated embodiment, the electronic controller 18 is programmed to weigh the RTV values recorded for lower indices N to be higher than RTV values recorded for higher indices N. The weighted index values N will be used to calculate a location score for each location stored in the storage 16, as will be described below. To put simply, the electronic controller 18 programmed to categorize the location score for each vehicle visit location based on how many times the vehicle visit location is an end location after vehicle travel. Therefore, the vehicle home setting device 10 of the illustrated embodiment provides for the technological improvement of more accurately determining a true home location for the vehicle 12 by estimating, categorizing or determining the home location based on calculated intermediary stop values over time.

Referring still to FIG. 4, the index N values are weighted by predetermined weight values w that are the highest when the index N is lower. FIG. 4 illustrates a sample weight value w for each of the indices N showing that the weighted value for the RTV value at each index N decreases as the index N increases. For example, in the sample weight values w below, the values for weight values w are predetermined and decrease in value as the index N increases such that the RTV value for N=1 will be weighted higher than the RTV value for N=2 and so on:

$$Weights ( w ) = [ w = 1 for N = 1 , w = 0.75 for N = 2 , w = 0.5 for N = 3 , w = 0.25 for N = 5 , w = 0.1 \; 25 for N = 6 , w = 0.0 \; 675 for N = 7 … ]$$

where w=1 for the first index N (i.e., N=1), w=0.75 for the second index N (i.e., N=2), w=0.5 for the third index N (i.e., N=3), w=0.25 for the fourth index (i.e., N=4), and so on.

The location score for each visited location is calculated based on the sum of the weighted values w for each corresponding index N and the RTV value of that corresponding index N as shown in Formula 1:

$$Formula 1$$

$$Location scores = rtv [ 0 ] ⋆ w [ 0 ] + rt v [ 1 ] ⋆ w [ 1 ] + rt v [ 2 ] ⋆ w [ 2 ] + …$$

where the value RTV for the first index N (N=1) (i.e., RTV[0] or recorded number of zero intermediary stops recorded) is multiplied by the weighted score of the first index N (w for N=1), the RTV for the second index N (N=2) (i.e., RTV[1] or recorded number of one intermediary stop recorded) is multiplied by the weighted score of the second index N (w for N=2), and so on. Therefore, for L1 in the scenario illustrated in FIG. 3, the location score is calculated as follows:

$$Score ( QJ 53 + 6 H ) = ( 11 ⋆ 1 ) + ( 9 ⋆ 0.75 ) + ( 9 ⋆ 0.5 ) + ( 5 ⋆ 0.25 ) + … = 23.75$$

The visited location having the highest location score is the designated home location. That is, the electronic controller 18 is programmed to calculate a location score for each vehicle visit location. The electronic controller 18 categorizes the one or more home locations based on the location scores with the higher location scores designating the home locations.

In the illustrated embodiment, the vehicle home setting device 10 is programmed to weigh RTV values for the indices N when the index N is lower as this lower index N corresponds to fewer intermediary stops. That is, at the first index N (N=1), the value for RTV is recorded for each roundtrip having zero (0) intermediary stops taken between leaving and returning to a corresponding location. At the second index N (N=2), the value for RTV is recorded for each roundtrip having one (1) intermediary stop taken between leaving and returning to a corresponding location.

To put simply, the electronic controller 18 is programmed to increase the location score for the end location when the calculated number of the intermediary stop locations for vehicle travel having the end location is low. In particular, the electronic controller 18 is programmed to increase the location score for the end location when determining a lower index N has a higher roundtrip vector value RTV for the vehicle visit location (i.e., the RTV value for lower N values for the end location is high). The electronic controller 18 is programmed to decrease the location score for the end location when the calculated number of intermediary stop locations for vehicle travel having the end location is high. The electronic controller 18 is programmed to decrease the location score for the end location when determining a lower index has a lower roundtrip vector value for the vehicle visit location (i.e., the RTV value for the lower N value for the end location is high).

Therefore, the electronic controller 18 is programmed to categorize the end locations as one or more home locations of the vehicle 12 in the storage 16 based on a calculated number of the intermediary stop locations preceding the end locations during vehicle travel. In FIG. 4, L1 is categorized higher than the L2 which is categorized higher than the L3 in terms of determining the vehicle's home location.

The electronic controller 18 is programmed to categorize or determine a first home location (e.g., L1) based on a first number of intermediary stop locations between a first start location and a corresponding first end location. That is, the first number of intermediary stop locations are visited between leaving and returning to the first home location. As stated, the first start location and the corresponding first end location are the same location. In this scenario and example, the electronic controller 18 is programmed to set the first home location (i.e., L1) as the home location stored in the storage 16.

The electronic controller 18 is programmed to continuously monitor and calculate location scores for visited locations as the vehicle accumulates more vehicle travel or trip locations which is collected by the vehicle tracking unit 14. The electronic controller 18 can update the home location with a new home location based on additional vehicle travel information. For example, the electronic controller 18 is programmed to reset the first home location stored in the storage 16 with a second home location based on a second number of intermediary stop locations of a second roundtrip when the second number of intermediary stop locations is lower than the first number of intermediary stop locations. In other words, the electronic controller is programmed to categorize or determine the second home location over the first home location upon determining that the second number of intermediary stop locations that are visited prior to returning to the second location are lower than the first number of intermediary stop locations.

The lower number of intermediary stops for the second location relative to the first location results in the location score for the second home location being higher than the location score for the first home location. As stated, the vehicle home setting device 10 is programmed weigh RTV values for the indices N when the index N is lower as this lower index N corresponds to fewer intermediary stops. As a result, the second home location has a higher location score when the calculated number of the intermediary stop locations for vehicle travel returning to the second home location is lower than that of the first home location. The electronic controller 18 is programmed to increase the location score for the second home location when the second home location is visited more often, such as the scenario when the second home location has been determined to incur more zero (0) intermediary stops during roundtrip scenarios.

In the illustrated embodiment, a method for determining a vehicle home location from among a plurality of vehicle visit locations is described above. The method comprises electronically collecting, by the vehicle tracking unit 12, vehicle visit locations of the vehicle during vehicle travel. The vehicle visit locations include vehicle trip start locations, vehicle trip end locations and vehicle trip intermediary stop locations visited between corresponding start and end locations.

The method further comprises electronically storing, by the storage 16, the vehicle visit locations during vehicle travel, the non-transitory computer readable medium storing vehicle roundtrip travel information having corresponding vehicle start and stop locations that are the same.

The method further comprises categorizing, by the electronic controller 18, the end locations as one or more home locations of the vehicle in the storage 16 based on a calculated number of the intermediary stop locations for vehicle roundtrip travel. The intermediary stop locations are locations that are visited by the vehicle during vehicle roundtrip travel that does not include the start and stop location in which the vehicle is turned OFF.

The method further comprises categorizing, by the electronic controller 18, a first home location of the one or more home locations based on a first number of intermediary stop locations that are visited prior to returning to the first home location.

The method further comprises categorizing, by the electronic controller 18, a second home location over the first home location upon determining that a second number of intermediary stop locations that are visited prior to returning to the second location are lower than the first number of intermediary stop locations.

The method further comprises categorizing, by the electronic controller 18, a location score for each vehicle visit location based on how many times the vehicle visit location is an end location after vehicle travel.

The method further comprises storing, by the storage 18, a plurality of roundtrip vector values RTV for each vehicle visit location, the roundtrip vector values RTV being based on a number of intermediary stop locations visited prior returning to each vehicle visit location.

The method further comprises storing, by the storage 18, indices N of roundtrip vector values RTV in which each index of the indices N corresponds to a recorded number of intermediary stop locations visited prior to returning to each vehicle visit location such that a lower index corresponds to a lower recorded number of intermediary stop locations.

The method further comprises increasing, by the electronic controller 18, a first location score for a first vehicle visit location when determining a lower index N (e.g., N=0 or N=1) has a higher roundtrip vector value RTV for the vehicle visit location.

The method further comprises decreasing, by the electronic controller 18, the first location score for the first vehicle visit location when determining the lower index N (e.g., N=0 or N=1) has a lower roundtrip vector value for the vehicle visit location.

The method further comprises categorizing, by the electronic controller 19, a home location based on the number of zero trip-counts stored in the non-transitory computer medium in which the calculated number of the intermediary stop locations for vehicle roundtrip travel equals zero.

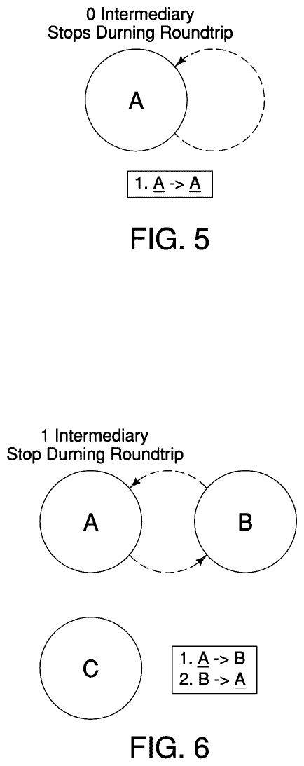

Referring to FIGS. 5 to 9, illustrative samples of vehicle roundtrip scenarios are illustrated for showing different intermediary stop scenarios for roundtrips. For example, FIG. 5 illustrates a pure roundtrip scenario where zero (0) intermediary stops are recorded for location A. Here, the vehicle 12 leaves location A and returns directly to location A.

FIG. 6 illustrates a roundtrip scenario having one (1) intermediary stop recorded. For example, the vehicle can leave location A for location B where it is stopped, then return from location B back to location A. The stop at location B is an intermediary stop in this scenario for location A.

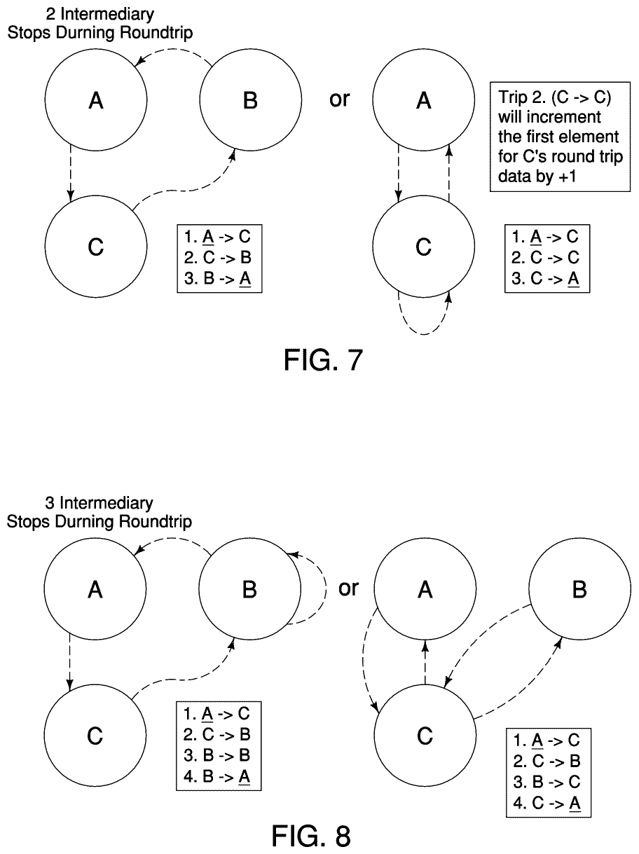

FIG. 7 illustrates roundtrip scenarios having two (2) intermediary stops recorded. For example, the vehicle 12 can leave location A for location C where it stops, then proceeds from location C to location B where it stops again before returning from location B back to location A. The stops at locations C and B are two (2) intermediary stops for location A in this scenario. In another example, the vehicle 12 leaves location A for location C, then leaves location C and returns again to location C before returning back to location A. In this scenario, the two stops at location C are two (2) intermediary stops in this scenario for location A.

FIG. 8 illustrates roundtrip scenarios having three (3) intermediary stops recorded. For example, the vehicle 12 can leave location A for location C where it stops, then proceeds from location C to location B where it stops again. At location B, the vehicle takes a roundtrip with no intermediary stops before returning back to B and then returning from location B back to location A. Here, the stop at location C and the two stops at location B amount to three (3) intermediary stops for a roundtrip taken from location A.

Also shown in FIG. 8, the vehicle 12 can alternatively leave from location A to location C, proceed from location C to location B, go from location B back to C, then back to location A. In this scenario, the vehicle accumulates three (3) intermediary stops for a roundtrip taken from location A. As shown, the scenario for a pure roundtrip scenario illustrated in FIG. 5 should be weighted more heavily than for the roundtrips illustrated in FIG. 8 as a location that is a home location should more likely incur roundtrips with zero (0) or a lower level of intermediary stops therebetween.

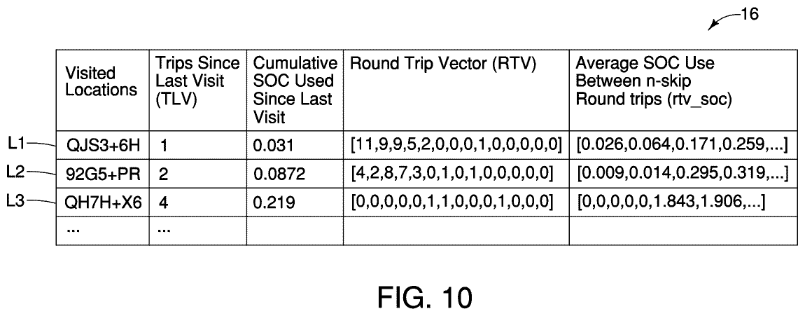

As mentioned, the vehicle home setting device 10 can be implemented for the technical contribution of improving vehicle charging control and calculation of charging schedules. Therefore, the vehicle home setting device 10 of the illustrated embodiment provides the technical contribution of improving the technical field of electronically calculating vehicle charging schedules depending on vehicle location. For example, referring to FIG. 10, the storage 16 can store a state-of-charge data for the vehicle's battery for each vehicle stop location in which the vehicle is turned OFF. The electronic controller 18 is programmed to generate a charging schedule for the vehicle upon based on the categorization of the one or more vehicle home locations, and the charging schedule are based on the vehicle travel history.

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Also as used herein to describe the above embodiment(s), the following directional terms “forward”, “rearward”, “above”, “downward”, “vertical”, “horizontal”, “below” and “transverse” as well as any other similar directional terms refer to those directions of a vehicle equipped with the vehicle home setting device. Accordingly, these terms, as utilized to describe the present invention should be interpreted relative to a vehicle equipped with the vehicle home setting device.

The term “detect” as used herein to describe an operation or function carried out by a component, a section, a device or the like includes a component, a section, a device or the like that does not require physical detection, but rather includes determining, measuring, modeling, predicting or computing or the like to carry out the operation or function.

The term “configured” as used herein to describe a component, section or part of a device includes hardware and/or software that is constructed and/or programmed to carry out the desired function.

The terms of degree such as “substantially”, “about” and “approximately” as used herein mean a reasonable amount of deviation of the modified term such that the end result is not significantly changed.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Every feature which is unique from the prior art, alone or in combination with other features, also should be considered a separate description of further inventions by the applicant, including the structural and/or functional concepts embodied by such feature(s). Thus, the foregoing descriptions of the embodiments according to the present invention are provided for illustration only, and not for the purpose of limiting the invention as defined by the appended claims and their equivalents.

What is claimed is:

1. A vehicle home setting device comprising:
a vehicle tracking unit provided at a vehicle, the vehicle tracking unit electronically collecting vehicle visit locations of the vehicle during vehicle travel, the vehicle visit locations including vehicle trip start locations, vehicle trip end locations and vehicle trip intermediary stop locations visited between corresponding start and end locations;
a non-transitory computer readable medium electronically storing the vehicle visit locations during vehicle travel, the non-transitory computer readable medium storing vehicle roundtrip travel information having corresponding vehicle start and stop locations that are the same; and
an electronic controller programmed to categorize the end locations as one or more home locations of the vehicle in the non-transitory computer readable medium based on a determination of vehicle start and end locations during vehicle round trip travel.

2. The vehicle home setting device according to claim 1, wherein
the electronic controller programmed to categorize the end locations based on a calculated number of the intermediary stop locations for vehicle roundtrip travel, the intermediary stop locations being locations that are visited by the vehicle during vehicle roundtrip travel that does not include the start and stop location in which the vehicle is turned off.

3. The vehicle home setting device according to claim 2, wherein
the electronic controller being programmed to categorize a location score for each vehicle visit location based on how many times the vehicle visit location is an end location after vehicle travel, with the electronic controller determining that a higher location score corresponds to a home location.

4. The vehicle home setting device according to claim 3, wherein
the non-transitory computer readable medium stores a plurality of roundtrip vector values for each vehicle visit location, the roundtrip vector values being based on a number of intermediary stop locations visited prior returning to each vehicle visit location.

5. The vehicle home setting device according to claim 4, wherein
the non-transitory computer readable medium stores indices of roundtrip vector values in which each index of the indices corresponds to a recorded number of intermediary stop locations visited prior to returning to each vehicle visit location such that a lower index corresponds to a lower recorded number of intermediary stop locations.

6. The vehicle home setting device according to claim 5, wherein
the electronic controller is programmed to increase a location score for a vehicle visit location when determining a lower index has a higher roundtrip vector value for the vehicle visit location.

7. The vehicle home setting device according to claim 6, wherein
the electronic controller is programmed to decrease the location score for the vehicle visit location when determining a lower index has a lower roundtrip vector value for the vehicle visit location.

8. The vehicle home setting device according to claim 3, wherein
the electronic controller is programmed to increase the location score for the end location when the calculated number of the intermediary stop locations for vehicle travel having the end location is low, and
the electronic controller is programmed to decrease the location score for the end location when the calculated number of intermediary stop locations for vehicle travel having the end location is high.

9. The vehicle home setting device according to claim 8, wherein
the non-transitory computer readable medium stores a state-of-charge data for the vehicle's battery for each vehicle stop location in which the vehicle is turned OFF.

10. The vehicle home setting device according to claim 9, wherein
the electronic controller is programmed to generate a charging schedule for the vehicle upon based on the categorization of the one or more vehicle home locations, the charging schedule being based on the vehicle travel history.

11. The vehicle home setting device according to claim 2, wherein
the electronic controller is programmed to categorize a home location based on the number of zero trip-counts stored in the non-transitory computer medium in which the calculated number of the intermediary stop locations for vehicle roundtrip travel equals zero.

12. The vehicle home setting device according to claim 2, wherein
the electronic controller is programmed to categorize a first home location of the one or more home locations based on a first number of intermediary stop locations that are visited prior to returning to the first home location,
the electronic controller is programmed to categorize a second home location over the first home location upon determining that a second number of intermediary stop locations that are visited prior to returning to the second location are lower than the first number of intermediary stop locations.

13. A method for determining a vehicle home location from among a plurality of vehicle visit locations, the method comprising:
electronically collecting, by a vehicle tracking unit, vehicle visit locations of the vehicle during vehicle travel, the vehicle visit locations including vehicle trip start locations, vehicle trip end locations and vehicle trip intermediary stop locations visited between corresponding start and end locations;
electronically storing, by a non-transitory computer readable medium, the vehicle visit locations during vehicle travel, the non-transitory computer readable medium storing vehicle roundtrip travel information having corresponding vehicle start and stop locations that are the same; and
categorizing, by an electronic controller, the end locations as one or more home locations of the vehicle in the non-transitory computer readable medium based on a calculated number of the intermediary stop locations for vehicle roundtrip travel, the intermediary stop locations being locations that are visited by the vehicle during vehicle roundtrip travel that does not include the start and stop location in which the vehicle is turned off.

14. The method according to claim 13, further comprising
categorizing, by the electronic controller, a first home location of the one or more home locations based on a first number of intermediary stop locations that are visited prior to returning to the first home location,
categorizing, by the electronic controller, a second home location over the first home location upon determining that a second number of intermediary stop locations that are visited prior to returning to the second location are lower than the first number of intermediary stop locations.

15. The method according to claim 14, further comprising
categorizing, by the electronic controller, a location score for each vehicle visit location based on how many times the vehicle visit location is an end location after vehicle travel.

16. The method according to claim 15, further comprising
storing, by the non-transitory computer readable medium, a plurality of roundtrip vector values for each vehicle visit location, the roundtrip vector values being based on a number of intermediary stop locations visited prior returning to each vehicle visit location.

17. The method according to claim 16, further comprising
storing, by the non-transitory computer readable medium, indices of roundtrip vector values in which each index of the indices corresponds to a recorded number of intermediary stop locations visited prior to returning to each vehicle visit location such that a lower index corresponds to a lower recorded number of intermediary stop locations.

18. The method according to claim 17, further comprising
increasing, by the electronic controller, a first location score for a first vehicle visit location when determining a lower index has a higher roundtrip vector value for the vehicle visit location.

19. The method according to claim 18, further comprising
decreasing, by the electronic controller, the first location score for the first vehicle visit location when determining the lower index has a lower roundtrip vector value for the vehicle visit location.

20. The method according to claim 19, further comprising
categorizing, by the electronic controller, a home location based on the number of zero trip-counts stored in the non-transitory computer medium in which the calculated number of the intermediary stop locations for vehicle roundtrip travel equals zero.
